(19) United States
(12) Patent Application Publication
(10) Pub. No.: US 2024/0304703 A1
(43) Pub. Date: Sep. 12, 2024

(54) METHOD OF FABRICATING LEAST DEFECTIVE NON-PLANAR BIPOLAR HETEROSTRUCTURE TRANSISTORS

(71) Applicant: UNIVERSITY OF SOUTHERN CALIFORNIA, Los Angeles, CA (US)

(72) Inventors: Ajey Poovannummoottil JACOB, Los Angeles, CA (US); Rehan Rashid KAPADIA, Los Angeles, CA (US)

(73) Assignee: UNIVERSITY OF SOUTHERN CALIFORNIA, Los Angeles, CA (US)

(21) Appl. No.: 18/579,330

(22) PCT Filed: Jul. 14, 2022
(86) PCT No.: PCT/US2022/037174

§ 371 Date: Jan. 13, 2024

Related U.S. Application Data
(60) Provisional application No. 63/221,638, filed on Jul. 14, 2021.

(51) Int. Cl. H01L 29/66; H01L 21/02; H01L 29/20; H01L 29/737; H01L 29/778

(52) U.S. Cl. CPC H01L 29/66462; H01L 21/02458; H01L 21/02461; H01L 21/0254; H01L 21/02543; H01L 29/2003; H01L 29/66318; H01L 29/737; H01L 29/7786

(57) ABSTRACT

A method for fabricating low defective non-planar bipolar heterostructure transistors includes a steps of providing a substrate that is coated with a first dielectric layer when the substrate is not composed of a dielectric material. A layer of a first semiconductor material is formed by template liquid phase (TLP) crystal growth wherein a second dielectric layer is disposed over the first semiconductor material. A trench is patterned into the second dielectric layer. An intermediate heterostructure is formed by epitaxially growing second semiconductor material in the trench to form a fin structure therein. Various power transistor structures can be formed from the intermediate heterostructure.

### CROSS-REFERENCE TO RELATED APPLICATIONS

This application claims the benefit of U.S. provisional application Ser. No. 63/221,638 filed Jul. 14, 2021, the disclosure of which is hereby incorporated in its entirety by reference herein.

### TECHNICAL FIELD

In at least one aspect, methods for fabricating heterostructure transistors are provided.

### BACKGROUND

Epitaxial heterostructures with lattice mismatch generate defects thereby making epitaxial growth of single crystalline material on a dielectric challenging. Moreover, devices on high thermal conductivity and high electron conductivity substrates are also challenging to fabricate.

Accordingly, there is a need for improved techniques for fabricating low defect epitaxial heterostructures such as high electron conductivity devices, and in particular high power transistors.

### SUMMARY

In at least one aspect, a method for fabricating low defective non-planar heterostructure transistors is provided. The method includes a step of providing a substrate that is coated with a first dielectric layer when the substrate is not composed of a dielectric material. A layer of a first semiconductor material is formed by template liquid phase (TLP) crystal growth wherein a second dielectric layer is disposed over the first semiconductor material. A trench is patterned into the second dielectric layer. An intermediate heterostructure is formed by epitaxially growing second semiconductor material in the trench to form a fin structure therein. Various power transistor structures can be formed from the intermediate heterostructure.

In another aspect, a method of growing high-quality single-crystalline heterostructures through a sequential growth of non-epitaxial template followed by an epitaxial replacement fin growth technique for device applications is provided.

In another aspect, high-quality single-crystalline heterostructure material on dielectric materials is provided.

In another aspect, a method of growing high-quality single crystalline heterostructure through a sequential growth and patterning of non-epitaxial layer(s) followed by an epitaxial replacement fin growth technique for device applications.

In another aspect, novel structures and methods for bipolar junction and high-mobility electron transistors is provided.

In another aspect, the growth techniques set forth herein enable the monolithic formation of heterogeneous heterojunctions focusing on interfaces that will enable improved performance in power transistors such as bipolar junctions.

In another aspect, heteroepitaxial growth on substrates such as diamond, an active part of the electron and thermal conductivity is provided.

In another aspect, a crystal growth technique includes steps of depositing a layer of a Group III metal onto the first dielectric layer, depositing a second dielectric layer over the layer of a Group III metal, heating or annealing the layer of a Group III metal to form a liquid layer thereof; and exposing the layer of a Group III metal to a gas comprising a Group V atom to form the III-V material.

In another aspect, a crystal growth technique is a template liquid phase (TLP) crystal growth technique.

In another aspect, a high electron mobility transistor includes a substrate and a first dielectric layer disposed over the substrate. A layer of a first semiconductor material is disposed over and directly contacts the first dielectric layer without a separate adhesive layer. The layer of a first semiconductor material has a defect density of 10⁶ defects/cm² or less. A fin structure is composed of a second semiconductor material. The fin structure is epitaxially growth on the layer of a first semiconductor material. A metal gate layer is disposed on top of the fin structure. Finally, a source is disposed over the fin structure and positioned at a first side of the metal gate layer and a drain disposed over the fin structure and positioned at a second side of the metal gate layer where the first side is an opposite side to the second side. Advantageously, the electron mobility transistor can include an array of fin structures each having a metal contact position on the top thereof.

In another aspect, a bipolar junction transistor is provided. The bipolar junction transistor includes an electrically conductive substrate, a first dielectric layer disposed over the substrate, and a layer of a first semiconductor material disposed over and directly contacting the first dielectric layer without a separate adhesive layer. Characteristically, the layer of a first semiconductor material having a defect density of 10⁶ defects/cm² or less. A second dielectric layer is disposed over the layer of a first semiconductor material. A trench is defined by the second dielectric layer. A fin structure including a second semiconductor material is disposed in the trench. The fin structure is epitaxially growth on the layer of a first semiconductor material. A fin contact disposed on top of the fin structure. A first contact extends from a top surface of the second dielectric layer to the layer of a first semiconductor material while a second contact extends from a top surface of the second dielectric layer to the electrically conductive substrate. Advantageously, the bipolar junction transistor can includes an array of fin structures each having a metal contact position on the top thereof.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be made to the following detailed description, read in conjunction with the following drawings, wherein like reference numerals denote like elements and wherein:

FIG. 1. Schematic flowchart depicting a method for fabricating heterostructure transistors.

FIG. 2A. Schematic flowchart for depicting a method for fabricating a high electron mobility transistor.

FIG. 2B. Schematic flowchart depicting a method for fabricating an array of high electron mobility transistors.

FIG. 3A. Schematic flowchart for depicting a method for fabricating a bipolar junction transistor.

FIG. 3B. Schematic flowchart depicting a method for fabricating an array of bipolar junction transistors.

FIG. 4A. Schematic flowchart for depicting a method for fabricating an InP/InGaP bipolar junction transistor.

FIG. 4B. Schematic flowchart depicting a method for fabricating an array of InP/InGaP bipolar junction transistors.

### DETAILED DESCRIPTION

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the term “polymer” includes “oligomer,” “copolymer,” “terpolymer,” and the like; molecular weights provided for any polymers refers to weight average molecular weight unless otherwise indicated; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It must also be noted that, as used in the specification and the appended claims, the singular form “a,” “an,” and “the” comprise plural referents unless the context clearly indicates otherwise. For example, reference to a component in the singular is intended to comprise a plurality of components.

As used herein, the term “about” means that the amount or value in question may be the specific value designated or some other value in its neighborhood. Generally, the term “about” denoting a certain value is intended to denote a range within +/−5% of the value. As one example, the phrase “about 100” denotes a range of 100+/−5, i.e. the range from 95 to 105. Generally, when the term “about” is used, it can be expected that similar results or effects according to the invention can be obtained within a range of +/−5% of the indicated value.

As used herein, the term “and/or” means that either all or only one of the elements of said group may be present. For example, “A and/or B” shall mean “only A. or only B. or both A and B”. In the case of “only A”, the term also covers the possibility that B is absent, i.e. “only A, but not B”.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

The phrase “composed of” means “including” or “consisting of.” Typically, this phrase is used to denote that an object is formed from a material.

With respect to the terms “comprising,” “consisting of,” and “consisting essentially of,” where one of these three terms is used herein, the presently disclosed and claimed subject matter can include the use of either of the other two terms.

The term “one or more” means “at least one” and the term “at least one” means “one or more.” The terms “one or more” and “at least one” include “plurality” and “multiple” as a subset. In a refinement, “one or more” includes “two or more.”

The term “substantially,” “generally,” or “about” may be used herein to describe disclosed or claimed embodiments. The term “substantially” may modify a value or relative characteristic disclosed or claimed in the present disclosure. In such instances, “substantially” may signify that the value or relative characteristic it modifies is within ±0%, 0.1%, 0.5%, 1%, 2%, 3%, 4%, 5% or 10% of the value or relative characteristic.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

When referring to a numeral quantity, in a refinement, the term “less than” includes a lower non-included limit that is 5 percent of the number indicated after “less than.” For example, “less than 20” includes a lower non-included limit of 1 in a refinement. Therefore, this refinement of “less than 20” includes a range between 1 and 20. In another refinement, the term “less than” includes a lower non-included limit that is, in increasing order of preference, 20 percent, 10 percent, 5 percent, or 1 percent of the number indicated after “less than.”

For all compounds or materials expressed as an empirical chemical formula with a plurality of letters and numeric subscripts (e.g., CH₂O), values of the subscripts can be plus or minus 50 percent of the values indicated rounded to or truncated to two significant figures. For example, if CH₂O is indicated, a compound of formula C_{(0.8-1.2)}H_{(1.6-2.4)}O_{(0.8-1.2)}. In a refinement, values of the subscripts can be plus or minus 30 percent of the values indicated rounded to or truncated to two significant figures. In still another refinement, values of the subscripts can be plus or minus 20 percent of the values indicated rounded to or truncated to two significant figures.

Throughout this application, where publications are referenced, the disclosures of these publications in their entireties are hereby incorporated by reference into this application to more fully describe the state of the art to which this invention pertains.

### Abbreviations

“HEMT” means high electron mobility transistor formation.

“TLP” means template liquid phase.

“EUV” means extreme ultraviolet radiation.

“LELE” means litho-etch-litho-etch.

“MOCVD” means metal-organic chemical vapor deposition.

“RIE” means reactive-ion etching.

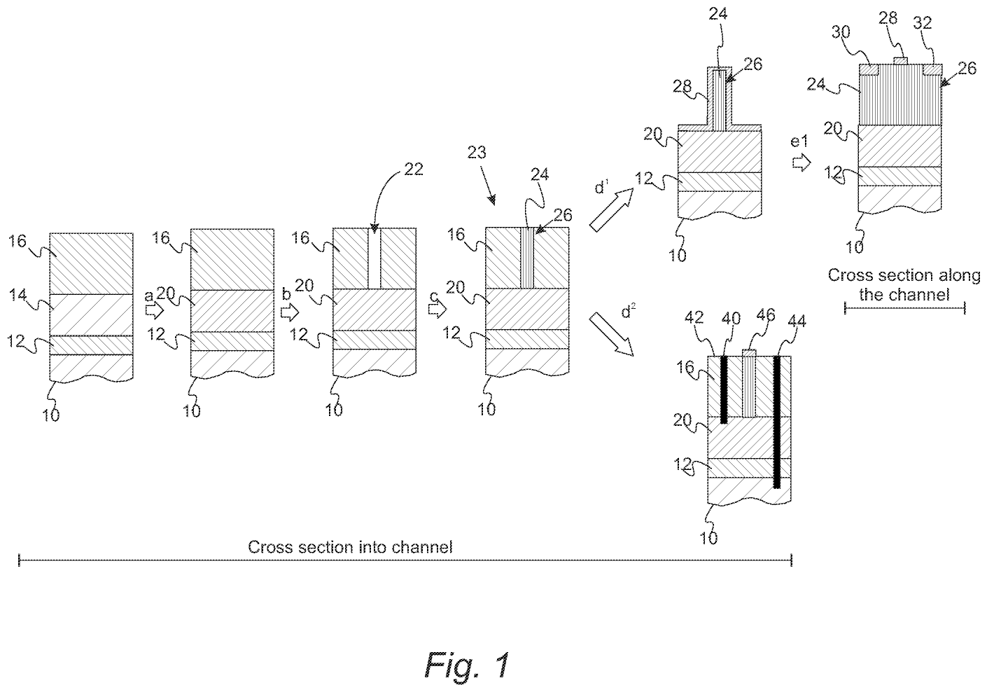

Referring to FIG. 1, a schematic flowchart of a method for fabricating low defect non-planar heterostructure transistors (e.g., a bipolar transistor) is provided. Advantageously, the heterostructure transistor can be a bipolar junction transistor (BJT) or a CMOS transistor or a bi-CMOS transistor or a high electron mobility transistor (HEMT) or a heterojunction bipolar transistor (HBT). In general, the method grows a high purity single crystalline heterostructure through a non-epitaxial template technique followed by a replacement epitaxial fin growth technique. In this context, a fin is a structure having a thickness that is less than both its length and width. The method starts with substrate 10 which can be an insulator, a semiconductor, an electrical conductor, and/or thermal conductor. In a variation, the substrate is composed of a group IV material. Examples of group IV materials include silicon, germanium, diamond, and combinations thereof. In another variation, the substrate is composed of a group III-V material. Examples of group III-V materials GaAs, GaN, AlN, or combinations thereof. Specific examples of suitable substrates are composed of diamond, aluminum oxide, crystalline silicon, silicon dioxide, silicon dioxide-based glass or quartz, and the like. When the substrate is not composed of a dielectric material, the substrate is coated with a first dielectric layer 12 (e.g., a SiO₂ layer). First dielectric layer 12 can be thermally formed on silicon (e.g., SiO₂). In a refinement, the first dielectric layer 12 can be deposed by CVD on diamond or other substrates. In a refinement, the first dielectric material is composed of SiO₂ and/or SiN deposited on to the substrate.

Still referring to FIG. 1, In step a), layer 20 of a first semiconductor material is formed by template liquid phase (TLP) crystal growth wherein a second dielectric layer 16 is disposed over layer 20 of a first semiconductor material. For example with respect to template liquid phase (TLP) crystal growth, layer 14 of a group III metal is deposited onto first dielectric layer 12. Layer 14 of the Group III metal is coated with second dielectric layer 16. The layer 14 of the Group III metal is heated or annealed to form a liquid layer. Layer 14 of Group III metal in the liquid state is exposed to a gas comprising a Group V atom to form layer 20 of a first semiconductor material. For example, the gases comprising a Group V atom can be nitrogen gas or a phosphorus-containing gas (e.g., phosphine). In a refinement, the first semiconductor material is an III-V material. Examples of III-V materials include but are not limited to gallium nitride, indium phosphide, and the like. The layer of a first semiconductor material typically has a defect density of 10⁶ defects/cm² or less. In a refinement, the layer of a first semiconductor material has a defect density of 10⁵ defects/cm² or les

In step b), trench 22 is patterned into the second dielectric layer 16. Trench 22 can be formed using e-beam lithography, EUV lithography, or LELE patterning techniques followed by etching (e.g., RIE) to form the trench. In step c), intermediate heterostructure 23 is formed by epitaxially growing second semiconductor material 24 into the trench to form a fin structure 26. In a refinement, fin structure 26 has a height less than about 60 nm and a width less than or equal to 10 nm. Second semiconductor material 24 can be epitaxially grown by MOCVD. Fin structure 26 typically has a defect density of 10⁶ defects/cm² or less. In a refinement, fin structure 26 has a defect density of 10⁵ defects/cm² or less. Examples of the second semiconductor material include but are not limited to gallium nitride, aluminum gallium nitride, indium gallium phosphide, indium phosphide, indium nitride, aluminum nitride, and combinations thereof. Fin structure 26 can be coated with a layer of a high K material. Table 1 provides non-limiting examples for intermediate heterostructure 23.

TABLE 1
Intermediate heterostructure examples.

| | First | first | Second | Second |
|---|---|---|---|---|
| | Dielectric | semiconductor | semiconductor | dielectric |
| Substrate | layer 12 | material | material | material |
| Si | SiO₂ or SiN | GaN | GaN and/or | SiO₂ or SiN |
| | | | AlGaN | |
| Si | SiO₂ or SiN | InP | InGaAs | SiO₂ or SiN |
| Si | SiO₂ or SiN | GaAs | AlGaAs | SiO₂ or SiN |
| Diamond | SiO₂ or SiN | GaN | GaN and/or | SiO₂ or SiN |
| | | | AlGaN | |
| Diamond | SiO₂ or SiN | InP | InGaAs | SiO₂ or SiN |
| Al₂O₃ | | AlN | AlGaN | |
| Al₂O₃ | | AlGaN | GaN and/or | |
| | | | InGaN | |
| Quartz | SiO₂ | GaN | GaN and/or | SiO₂ or SiN |
| | | | AlGaN | |
| Ge (Germanium) | SiO₂ | GaAs or InP | GaInP, | SiO₂ or SiN |
| | | | GaInAs, | |

Various power transistor structures can be formed from intermediate heterostructure 23 as follows. For example, a high electron mobility transistor is formed as follows. In step d¹, second dielectric layer 16 is removed and a metal gate layer 28 is disposed over fin structure 26 and portions of layer 20. In step e¹, source 30 and drain 32 are deposited to form transistor 34. In a refinement, an array of fin structures are formed interposed between the source and drain. In a variation as described below in more detail, a source 30 is deposited onto the layer of a first semiconductor material at a first side of the metal gate layer. Similarly, drain 32 is deposited onto the layer of a first semiconductor material at a second side of the metal gate layer with the first side being an opposite side to the second side. In a refinement, the source and drain are independently composed of a semiconductor. In a refinement, the source and drain extend to the first semiconductor material.

In another example, a transistor (e.g., a bipolar transistor) is formed as follows. In step d², first contact 40 is formed from surface 42 of second dielectric layer 16 to layer 20 while second contact 44 is formed from surface 42 of second dielectric layer 16 to substrate 10. A fin contact 46 (e.g., a gate layer) is optionally deposited on top of the fin structure.

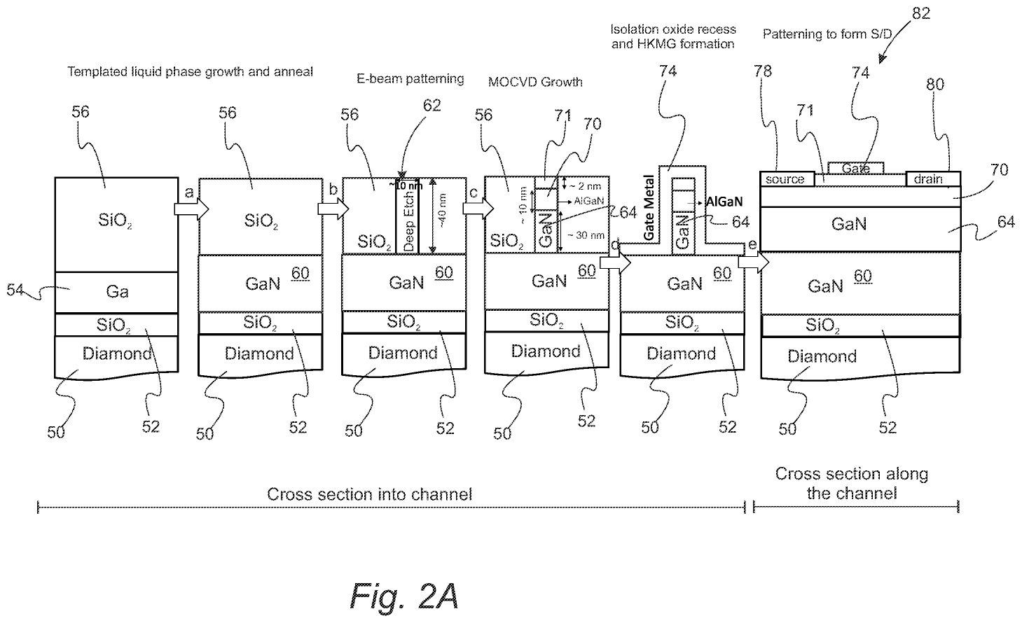

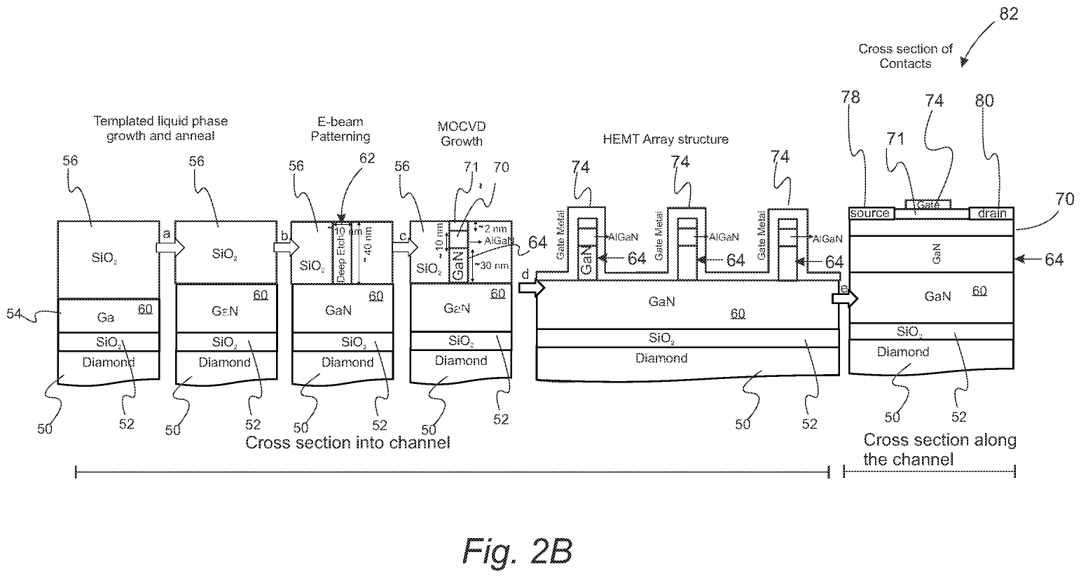

FIGS. 2A and 2B provide schematic flowcharts for a method of making high electron mobility transistors (HEMT). FIG. 2A shows the formation of a single HEMT while FIG. 2B shows the formation of an array of HEMTs. The method starts with a diamond substrate 50 that is coated with a thin layer of silicon dioxide 52. A gallium layer 54 is disposed between silicon dioxide 52 and silicon dioxide layer 56. In step a), gallium layer 54 is converted to a gallium nitride layer 60 by templated liquid phase growth and annealing. In step b), a trench 62 is formed in silicon dioxide layer 56 by a patterning technique such as e-beam patterning. In step c), fin structure 64 is epitaxially grown in trench 62. In a refinement, fin structure 64 is composed of gallium nitride that has been epitaxially grown onto gallium nitride layer 60. In a further refinement, fin structure 64 includes a sublayer 70 composed of aluminum gallium nitride. In another refinement, an option layer 71 of a high K dielectric is deposited over fin structure 64.

In step d), silicon dioxide layer 56 is removed and the fin 64 and exposed portion of gallium nitride layer 60 are coated with gate layer 74. FIG. 2B depicts a variation in which a plurality of fin structure 64 are interposed between source 78 and drain 80. In this variation, a plurality of fins 64 are disposed over gallium nitride layer 60 as shown in FIG. 2B. In step e), source 78 and drain 80 are then deposited to form transistor 82.

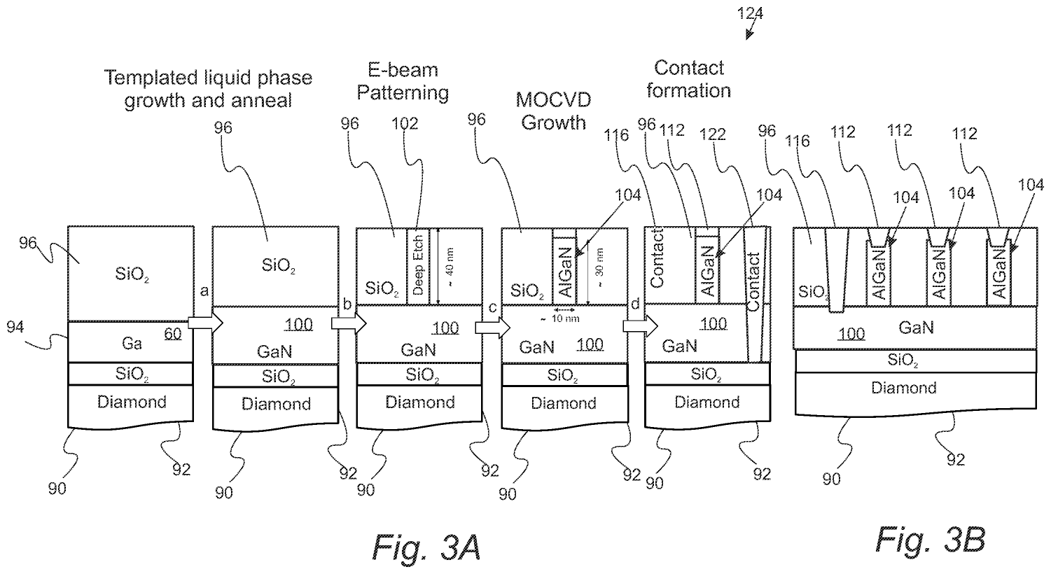

FIGS. 3A and 3B provide schematic flowcharts for a method of making bipolar junction transistors. FIG. 3A shows the formation of a single bipolar junction transistor while FIG. 3B shows the formation of an array of bipolar junction transistors. The method starts with a diamond substrate 90 that is coated with a thin layer of silicon dioxide 92. A gallium layer 94 is disposed between silicon dioxide 92 and silicon dioxide layer 96. In step a), gallium layer 94 is converted to a gallium nitride layer 100 by templated liquid phase growth and anneal. In step b), a trench 102 is formed in silicon dioxide layer 96 by a patterning technique such as e-beam patterning. In step c), fin structure 104 is epitaxially grown in trench 102. In a refinement, fin structure 104 is composed of gallium nitride that has been epitaxially grown onto gallium nitride layer 100. In step d), contact 112 is disposed on fin structure 104. Contact 116 is formed between the top surface of silicon dioxide layer 96 and gallium nitride layer 100 while contact 122 is formed between the top surface of silicon dioxide layer 96 and diamond substrate 90 to form bipolar transistor 124. FIG. 3B depicts a variation having a plurality of fin structure 10 interposed between contact 116 and contact 122.

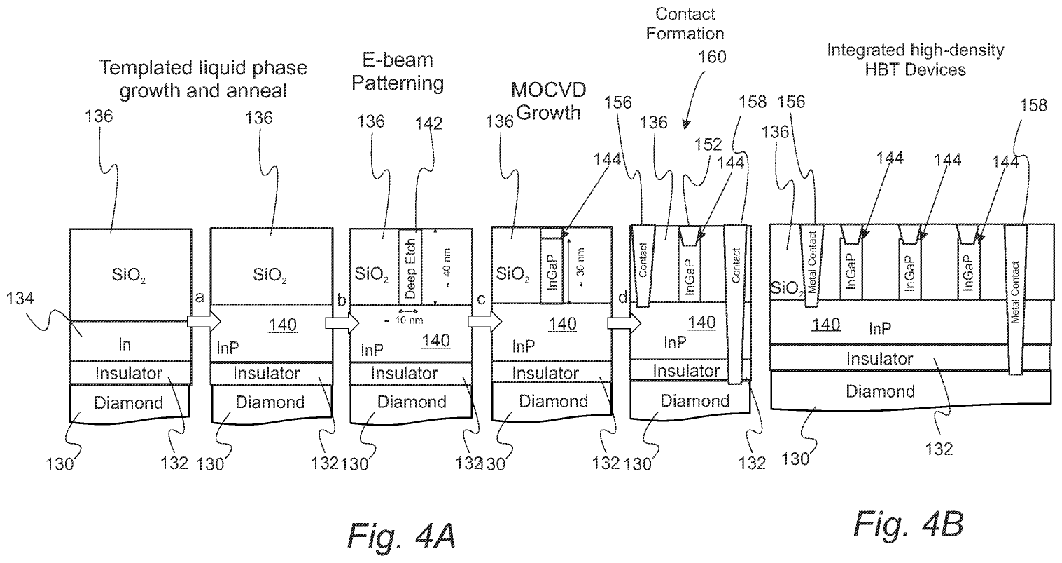

FIGS. 4A and 4B provide schematic flowcharts for a method of making InP/InGaP bipolar junction transistor. FIG. 4A shows the formation of a single InP/InGaP bipolar junction transistor while FIG. 4B shows the formation of an array of InP/InGaP bipolar junction transistors. The method starts with a diamond substrate 130 that is coated with a thin layer of silicon dioxide 132. An indium layer 134 is disposed between silicon dioxide layer 132 and silicon dioxide layer 136. In step a), indium layer 134 is converted to an indium phosphide layer 140 by templated liquid phase growth and annealing. In step b), a trench 142 is formed in silicon dioxide layer 136 by a patterning technique such as e-beam patterning. In step c), the fin structure 144 is epitaxially grown in trench 142. In a refinement, fin structure 144 is composed of indium gallium phosphide that has been epitaxially grown onto indium phosphide layer 140. In step d), contact 152 is disposed on fin structure 144. Contact 156 is formed between the top surface of silicon dioxide layer 136 and gallium nitride layer 100 while contact 158 is formed between the top surface of silicon dioxide layer 136 and diamond substrate 130 to form bipolar transistor 160. FIG. 4B depicts a variation having a plurality of fin structures 144 interposed between contact 156 and contact 158.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### REFERENCES

[1]. Methods of forming low defect replacement fins for a FinFET semiconductor device and the resulting devices, U.S. Pat. No. 9,614,058
[2]. Methods of forming replacement fins for a FinFET semiconductor device by performing a replacement growth process, U.S. Pat. No. 9,240,342
[3]. Method to form defect free replacement fins by H2 anneal, U.S. Pat. No. 9,165,837
[4]. A. P. Jacob, R. Xie, M. G. Sung, L. Liebmann, R. T. P. Lee and B. Taylor, Scaling Challenges for advanced CMOS Devices, Published in Scaling and Integration of High-Speed Electronics and Optomechanical Systems, Edited by M. Willanderand H. Pettersson, in Selected Topics in Electronics and Systems—Vol. 59 (editor in chief: M. S. Shur) World Scientific, Singapore, pp-1-76, ISB 978-981-3225-39-8 (2017)
[5]. A. P. Jacob, R. Xie, M. G. Sung, L. Liebmann, R. T. P. Lee and B. Taylor, Scaling Challenges for Advanced CMOS Devices, International Journal of High Speed Electronics and Systems, 26 (1), 1740001, (2017)

What is claimed is:

1. A method for fabricating a low defective non-planar heterostructure transistor comprising:
providing a substrate, the substrate being coated with a first dielectric layer when the substrate is not composed of a dielectric material;
forming a layer of a first semiconductor material by template liquid phase (TLP) crystal growth wherein a second dielectric layer is disposed over the first semiconductor material;
patterning a trench into the second dielectric layer; and
forming an intermediate heterostructure by epitaxially growing a second semiconductor material in the trench to form a fin structure therein.

2. The method of claim 1 wherein the heterostructure transistor is a bipolar junction transistor (BJT) or a CMOS transistor or a bi-CMOS transistor or a high electron mobility transistor (HEMT) or a heterojunction bipolar transistor (HBT).

3. The method of claim 2 wherein the substrate is composed of a group IV material.

4. The method of claim 3 wherein the group IV material. is selected from the group consisting of silicon, germanium, diamond, and combinations thereof.

5. The method of claim 2 wherein the substrate is composed of a group III-V material.

6. The method of claim 5 wherein the group III-V material is selected from the group consisting of GaAs, GaN, AlN, and combinations thereof.

7. The method of claim 5 wherein the first dielectric layer is SiO₂ or SiN deposited on to the substrate.

8. The method of claim 5 wherein a crystal growth technique includes step of:
depositing a layer of a Group III metal onto the first dielectric layer;
depositing a second dielectric layer over the layer of a Group III metal;
heating or annealing the layer of a Group III metal to form a liquid layer thereof; and
exposing the layer of a Group III metal to a gas comprising a Group V atom to form the III-V material.

9. The method of claim 8 wherein the crystal growth technique is template liquid phase (TLP) crystal growth.

10. The method of claim 8 wherein the III-V material is indium phosphide.

11. The method of claim 1, wherein the second semiconductor material is selected from the group consisting of gallium nitride, aluminum gallium nitride, indium phosphide, indium nitride, aluminum nitride, and combinations thereof.

12. The method of claim 1, wherein the second semiconductor material is aluminum gallium nitride.

13. The method of claim 1, wherein the second semiconductor material is indium gallium phosphide.

14. The method of claim 1, wherein the substrate is composed of diamond.

15. The method of claim 1, wherein the substrate is composed of aluminum oxide, silicon dioxide-based glass or quartz.

16. The method of claim 1 wherein the substrate is composed of crystalline silicon.

17. The method of claim 1 further comprising depositing a metal gate layer over the fin structure.

18. The method of claim 17, wherein a source is deposited onto the layer of a first semiconductor material at a first side of the metal gate layer; and a drain is deposited onto the layer of a first semiconductor material at a second side of the metal gate layer, the first side being an opposite side to the second side.

19. The method of claim 18, wherein the source and drain are independently composed of a semiconductor.

20. The method of claim 18 wherein an array of fin structures are formed interposed between the source and drain.

21. The method of claim 20 wherein the source and drain are formed on each fin structure.

22. The method of claim 20 wherein the source and drain extend to the first semiconductor material.

23. The method of claim 1 further comprising forming a fin contact, a first contact extending from a top surface of the second dielectric layer to the layer of a first semiconductor material and a second contact extending from a top surface of the second dielectric layer to the substrate.

24. The method of claim 23, wherein an array of fin structures are formed interposed between the first contact and the second contact.

25. A high electron mobility transistor comprising
a substrate;
a first dielectric layer disposed over the substrate;
a layer of a first semiconductor material disposed over and directly contacting the first dielectric layer without a separate adhesive layer, the layer of a first semiconductor material having a defect density of 10⁶ defects/cm² or less;
a fin structure disposed over and contacting the layer of a second semiconductor material, the fin structure being epitaxially grown on the layer of a first semiconductor material;
a metal gate layer dispose on top of the fin structure of a first semiconductor material;
a source disposed over the fin structure and positioned at a first side of the metal gate layer; and
a drain disposed over the fin structure and positioned at a second side of the metal gate layer, the first side being an opposite side to the second side.

26. The high electron mobility transistor of claim 25 further comprising an array of fin structures each having a metal contact position on the top thereof.

27. The high electron mobility transistor of claim 25, wherein first semiconductor material is a II-V material.

28. The high electron mobility transistor of claim 27, wherein the II-V material is gallium nitride.

29. The high electron mobility transistor of claim 27, wherein the II-v material is indium phosphide.

30. The high electron mobility transistor of claim 27, wherein the second semiconductor material is gallium nitride.

31. The high electron mobility transistor of claim 27, wherein the second semiconductor material is aluminum gallium nitride.

32. A bipolar junction transistor comprising:
an electrically conductive substrate;
a first dielectric layer disposed over the electrically conductive substrate;
a layer of a first semiconductor material disposed over and directly contacting the first dielectric layer without a separate adhesive layer, the layer of a first semiconductor material having a defect density of 10⁶ defects/cm²;
a second dielectric layer disposed over the layer of a first semiconductor material;
a trench defined by the second dielectric layer;
a fin structure composed of a second semiconductor material and disposed in the trench, the fin structure being epitaxially growth on the layer of a first semiconductor material;
a fin contact disposed on top of the fin structure;
a first contact extending from a top surface of the second dielectric layer to the layer of a first semiconductor material; and
a second contact extending from a top surface of the second dielectric layer to the electrically conductive substrate.

33. The bipolar junction transistor of claim 32 further comprising an array of fin structures each having a metal contact position on the top thereof.

34. The bipolar junction transistor of claim 32, wherein the electrically conductive substrate is composed of diamond.

35. The bipolar junction transistor of claim 32, wherein first semiconductor material is a III-V material.

36. The bipolar junction transistor of claim 35, wherein the III-V material is GaN, InP, AlN, AlGaN or a combination thereof.

37. The bipolar junction transistor of claim 35, wherein the III-V material is indium phosphide.

38. The bipolar junction transistor of claim 32, wherein the second semiconductor material is gallium nitride.

39. The bipolar junction transistor of claim 32, wherein the second semiconductor material is aluminum gallium nitride.
